(19) United States
(12) Patent Application Publication
(10) Pub. No.: US 2009/0073661 A1
(43) Pub. Date: Mar. 19, 2009

(54) THIN CIRCUIT MODULE AND METHOD

(75) Inventors: Mark Wolfe, Austin, TX (US); James Wilder, Austin, TX (US); David L. Roper, Austin, TX (US)

Correspondence Address: FISH & RICHARDSON P.C., P.O BOX 1022, Minneapolis, MN, 55440-1022, US

(73) Assignee: STAKTEK GROUP L.P., Austin, TX (US)

(21) Appl. No.: 11/857,235

(22) Filed: Sep. 18, 2007

(51) Int. Cl. H05K 1/14; H05K 3/00; H05K 7/20

(52) U.S. Cl. 361/720; 29/829; 361/737

(57) ABSTRACT

A circuit module includes a printed circuit board (PCB) having a first side, a second side, and a bottom perimeter edge. The PCB exhibits a first thickness along the bottom perimeter edge. The first side includes a recessed area and, in that recessed area, the PCB has a second thickness that is less than the first thickness. A plurality of integrated circuits (ICs) are fixed to the PCB in the recessed area. A plurality of module contacts are connected to the ICs and are disposed along at least one of the first and second sides and are configured to provide electrical connection between the circuit module and an edge connector.

### FIELD

The present invention relates to a thin circuit module and method for making the same.

### BACKGROUND

The well-known DIMM (Dual In-line Memory Module) board has been used for years, in various forms, to provide memory expansion. A typical DIMM includes a conventional PCB (printed circuit board) with memory devices and supporting digital logic devices mounted on both sides. The DIMM is typically mounted in the host computer system by inserting a contact-bearing edge of the DIMM into a card edge connector. A small outline DIMM (SODIMM) is a smaller alternative to a traditional DIMM. A SODIMM can be roughly half the size of a regular DIMM. As a result, SODIMMs can be used in notebooks, small footprint PCs (such as those with a Mini-ITX motherboard), high-end upgradable office printers and networking hardware like routers.

Many of the various types of DIMMs include an associated heat management structure, such as an external heat sink (EHS). The EHS helps manage a temperature of the DIMM. More specifically, heat that is generated by the integrated circuits (ICs) of the DIMM is transferred to the EHS and eventually to the atmosphere surrounding the DIMM. In this manner, the temperature of the DIMM can be regulated. Systems that employ DIMMs, however, often have very limited profile space for such devices. Further, the overall dimensions of a DIMM should fit within a standard envelope.

There remains a need to provide methods and structures for decreasing the size of a DIMM alone or in combination with an associated heat sink. SUMMARY

A circuit module includes a printed circuit board (PCB) having a first side, a second side, and a bottom perimeter edge. The PCB exhibits a first thickness along the bottom perimeter edge. The first side includes a recessed area and, in that recessed area, the PCB has a second thickness that is less than the first thickness. A plurality of integrated circuits (ICs) are fixed to the PCB in the recessed area. A plurality of module contacts are connected to the ICs and are disposed along at least one of the first and second sides and are configured to provide electrical connection between the circuit module and an edge connector.

The circuit module embodiments of the present disclosure exhibit a reduced overall thickness, as compared to conventional circuit modules. More specifically, the ICs are arranged on a thin portion of the PCB to reduce the extent to which each projects from the PCB. In this manner, the circuit module embodiments of the present disclosure can provide a high density of ICs, while fitting within a standardized envelope.

### BRIEF DESCRIPTION OF THE DRAWINGS

FIG. 1 depicts an exemplar module devised in accordance with the present disclosure.

FIG. 2A depicts a cross-section of an exemplar module along the line A-A of FIG. 1.

FIG. 2B depicts a cross-section of another exemplar module along the line A-A of FIG. 1.

FIG. 3 depicts an enlarged view of a portion of the cross-section of FIG. 2.

FIG. 4 depicts the exemplar module of FIG. 1 with an external heat sink (EHS) removed.

FIG. 5 depicts a cross-section of the exemplar module of FIG. 4 along the line B-B.

FIG. 6 depicts an exemplar printed circuit board (PCB) of the exemplar module of FIG. 1.

FIGS. 7A and 7B depict a cross-sections of exemplar PCBs taken along the line C-C of FIG. 6.

FIG. 8 depicts an enlarged view of a portion of the cross-section of FIG. 7.

FIG. 9 depicts another exemplar PCB in accordance with the present disclosure.

FIG. 10 depicts another exemplar module devised in accordance with the present disclosure and including the exemplar PCB of FIG. 9.

FIGS. 11-13 depict alternative exemplar PCBs in accordance with the present disclosure.

### DETAILED DESCRIPTION

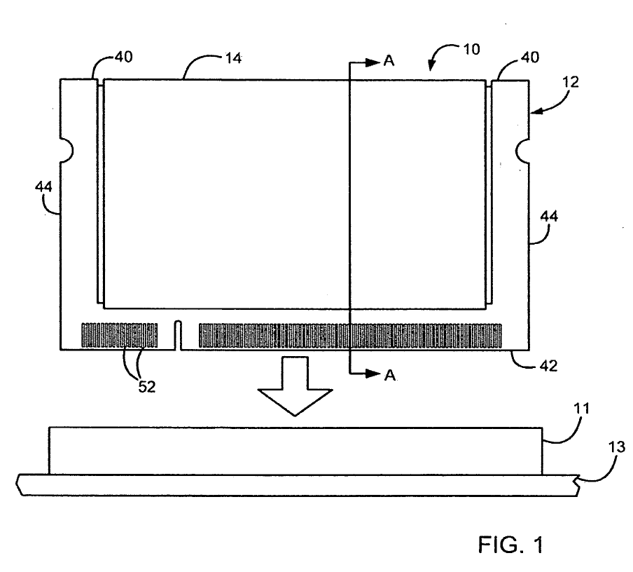

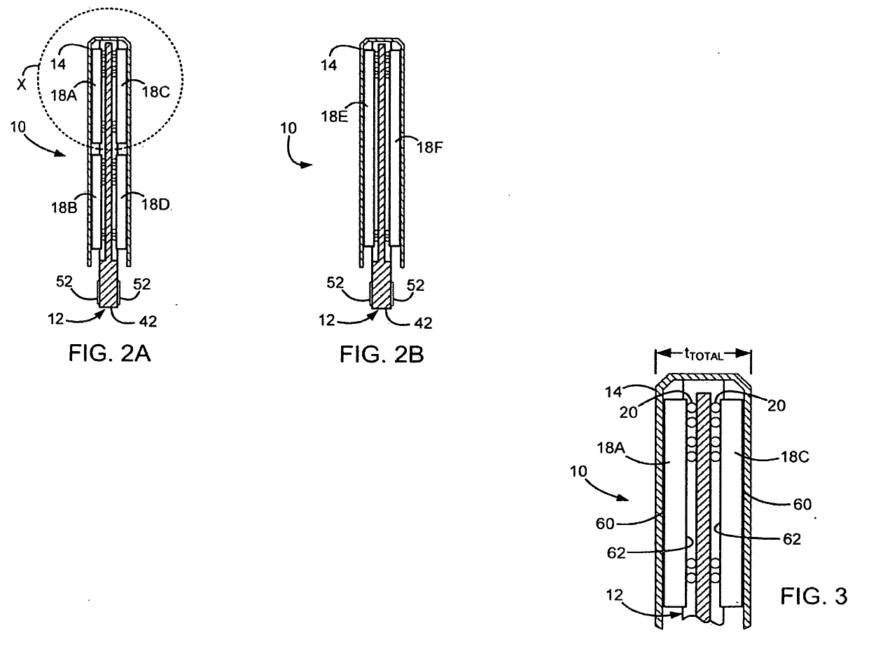

FIGS. 1-3 depict exemplar embodiments of a circuit module 10 in accordance with the present disclosure. Preferred embodiments of circuit module 10 include a rigid printed circuit board (PCB) 12 and a heat sink 14, but as those of skill in the art will appreciate, alternative embodiments may be devised from substrates other than PCB. The exemplar circuit module 10 of FIG. 2A includes a first plurality of ICs 18A, 18B arranged in first and second rows, and a second plurality of ICs 18C, 18D also arranged in first and second rows. The exemplar circuit module 10 of FIG. 2B, on the other hand, includes a first plurality of ICs 18E arranged in a single row, and a second plurality of ICs 18F arranged in a single row. PCB 12 functions as a rigid support substrate of circuit module 10 and can be provided, for example, as an FR4 type PCB. As described in further detail below, PCB 12 can comprise one or more conductive layers supported by one or more rigid, non-conductive substrate layers. Circuit module 10 is preferably configured to plug into an edge connector 11, which is attached to another circuit board 13.

FIGS. 18A-D; 18E-F can be chip-scale packaged memory devices of small scale. For purposes of this disclosure, the term chip-scale packaged or “CSP” refers to integrated circuitry of any function that is packaged to provide contacts 20 (often embodied as “bumps” or “balls” in an array, for example) along a major planar side of the package. CSP does not refer to leaded devices that provide connection to an integrated circuit within the package through leads emergent from at least one side of the periphery of the package such as, for example, a thin small-outline package (TSOP).

Embodiments of the present disclosure may be employed with leaded or CSP devices or other devices in both packaged and unpackaged forms. However, where the term CSP is used, the above definition for CSP should be adopted. Consequently, although CSP excludes leaded devices, references to CSP are to be broadly construed to include the large variety of array devices (and not to be limited to memory only), whether die-sized or other size such as BGA and micro BGA as well as flip-chip. As those of skill will understand after appreciating this disclosure, some embodiments of the present disclosure may be devised to employ stacks of ICs each disposed where an IC 18A-D; 18E-F is indicated in the exemplar figures.

Multiple integrated circuit die may be included in a package depicted as a single IC 18A-D; 18E-F. While in this embodiment, memory ICs 18A-D; 18E-F are used to provide a memory expansion board or module, various embodiments may include a variety of integrated circuits and other components. Such variety may include microprocessors, field-programmable gate arrays (FPGAs), radio-frequency (Rf) transceiver circuitry, digital logic, as a list of non-limiting examples, or other circuits or systems which may benefit from a high-density circuit board or module capability. A memory buffer, such as an advanced memory buffer (AMB), for example, or a controller can also be included.

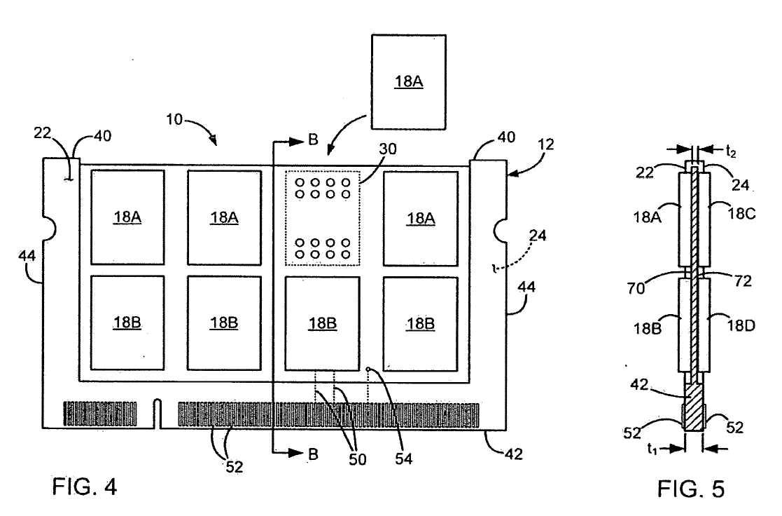

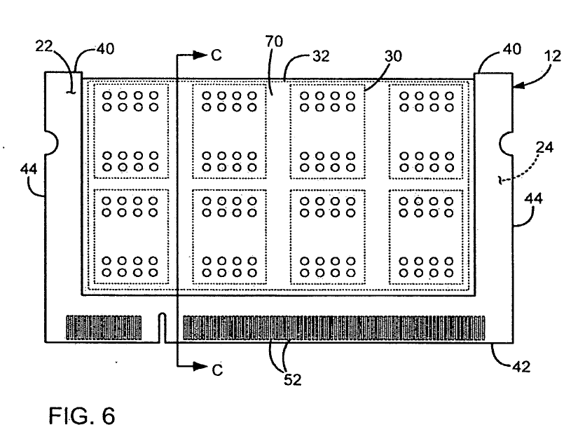

The depiction of FIGS. 4 and 5 shows exemplar circuit module 10 with heat sink 14 removed. PCB 12 includes first and second sides 22, 24 including at least one mounting contact array 30 for ICs 18A-D, for example. It is appreciated that a similar contact array can be provided and configured to accommodate ICs 18E-F. Contact arrays, such as depicted contact array 30, are disposed beneath ICs 18A-D; 18E-F. Exemplar contact array 30 is shown, as is an exemplar IC 18A, to be mounted at contact array 30. Plural contact arrays 30 define a contact array set 32 (see FIG. 6, for example).

Various discrete components such as termination resistors, bypass capacitors, and bias resistors, in addition to the buffers or ICs, may be mounted on either or both of sides 22, 24 of PCB 12. Such discrete components are not shown to simplify the drawing. PCB 12 may also be depicted with reference to its perimeter edges, two of which are typically long, a top perimeter edge 40 and a bottom perimeter edge 42, for example, and two typically shorter side perimeter edges 44. Other embodiments may employ a PCB that is not rectangular in shape and may be square, in which case the perimeter edges would be of equal size, or other convenient shape to adapt to manufacturing particulars. Other embodiments may also have fewer or greater numbers of ICs on one side 22, 24 of PCB 12.

Referring back to FIG. 4, exemplar conductive traces 50 are illustrated and connect module contacts 52 to ICs 18A-18D. It is appreciated that similar traces can be provided and configured to accommodate ICs 18E-F. Those of skill will understand that there are many such traces 50 in a typical embodiment. Traces 50 may also connect to vias 54 that may transit between conductive layers of PCB 12 in certain embodiments having more than one conductive layer. In a some embodiments, vias 54 may connect ICs 18A-18D on one side of PCB 12 to module contacts 52. Similarly, vias 54 can connect ICs 18E-F on one side of PCB 12 to module contacts 52. Traces 50 may make other connections between the ICs 18A-D; 18E-F on either side of PCB 12 and may traverse the rows of module contacts 52 to interconnect the ICs 18A-18I); 18E-F. Together, the various traces 50 and vias 54 make interconnections needed to convey data and control signals amongst the various ICs 18A-18D; 18E-F and other circuits including, but not limited, to buffer circuits. Those of skill will understand that other embodiments can include a single row of module contacts 52 and can, in other embodiments, include a module 10 bearing ICs 18A-18D; 18E-F on only one side of PCB 12.

FIG. 2A is a cross section view of an exemplar circuit module 10 taken along the line A-A of FIG. 1. FIG. 3 is an enlarged view of the area X in FIG. 2. ICs 18A-D include a top surface 60 and a bottom surface 62. In the depicted embodiment, heat sink 14 can be attached in heat exchange contact to top surface 60 of one or more of ICs 18A-D. As used herein, the term heat exchange contact indicates that heat transfer can occur between the ICs and heat sink 14. Heat sink 14 can be attached using various methods including, but not limited to, providing an adhesive layer (not shown) between a surface of heat sink 14 and one or more of top surfaces 60 of ICs 18A-18D. In the depicted embodiment of FIG. 2A, each IC 18A-18D is attached to PCB 12 at contacts 20. FIG. 2B is a cross section view of an alternative exemplar circuit module 10 also taken along the line A-A of FIG. 1. ICs 18E-F of FIG. 2B are coupled to PCB 12 and heat sink 14, as similarly described with respect to ICs 18A-D. Circuit module 10 includes a total thickness (t_{TOTAL}). t_{TOTAL} is preferably equal to or less than a standard thickness, such as a JEDEC thickness envelope (e.g., 3.80 mm maximum), for example. This is achieved by using any of the various embodiments of PCB 12, as described herein.

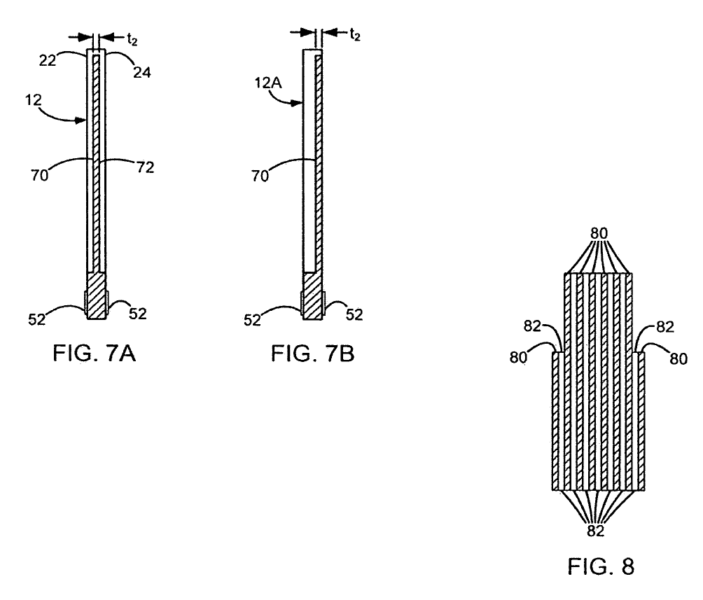

As seen in FIGS. 4-8, PCB 12 includes a recessed area. In the embodiment of FIGS. 2A, 2B, 5 and 7A, PCB 12 include a first recessed area 70 on side 22 and a second recessed area 72 on side 24. PCB 12 includes a first thickness (t₁) along bottom perimeter edge 42 in the area of the module contacts 52. In some embodiments, PCB 12 can include first thickness (t₁) along one or more of side perimeter edges 44 and top perimeter edge 42, or along only portions of side perimeter edges 44 and/or top perimeter edge 42. PCB 12 includes a second thickness (t₂) between recessed areas 70, 72. First thickness (t₁) is greater than second thickness (t₂). In one non-limiting example, first thickness (t₁) can be 1.00 mm±a first pre-defined tolerance, and second thickness (t2) can be 0.50 mm±a second pre-defined tolerance. In the exemplar embodiment depicted in FIG. 7B, a PCB 12A includes a recessed area 70 in only side 22.

In various embodiments described herein, contact arrays 30 for ICs 18A-D; 18E-F are formed in recessed areas 70, 72. Consequently, ICs 18A-D; 18E-F attach to PCB 12, 12A at a thin portion of PCB 12, 12A (i.e., recessed areas 70, 72) to reduce the overall thickness of circuit module 10. The thicker portions of PCB 12, 12A (e.g., bottom perimeter edge 42 and side perimeter edges 44) provide additional strength and rigidity to PCB 12, 12A. In this manner, PCB 12, 12A has sufficient strength to withstand forces applied thereto, as circuit module 10 is plugged into a corresponding socket such as edge connector 11, for example.

Referring to FIG. 8, PCB 12 can include conductive layers 80 and non-conductive layers 82 separating conductive layers 80. Conductive layers 80 can provide electrical connections within PCB 12. PCB 12 can be manufactured using various methods including, but not limited to, subtractive or additive processes. In one embodiment, PCB 12 is formed by adhering a conductive layer over a non-conductive substrate, and removing (e.g., by etching) unwanted portions of the conductive layer after applying a temporary mask, for example. In this manner, only the desired conductive traces remain. In another embodiment, the conductive traces can be adhered to a bare, non-conductive substrate or a substrate (e.g., by electroplating). Additional conductive layers and non-conductive layers can be subsequently added to define PCB 12.

In one embodiment, the recessed areas can be defined by subsequently removing layers. For example, a PCB can be provided having first thickness (t₁) across it's entirety. Portions of the outer conductive and non-conductive layers can be removed to reduce the thickness of the PCB in particular areas, such that the PCB includes second thickness (t₂) in those particular areas. In another embodiment, a PCB can be provided having second thickness (t₂) across it's entirety. Subsequently, additional conductive and non-conductive layers can be added to particular areas (e.g., the top, bottom and/or side perimeter edges), such that the PCB includes first thickness (t₁) in those particular areas.

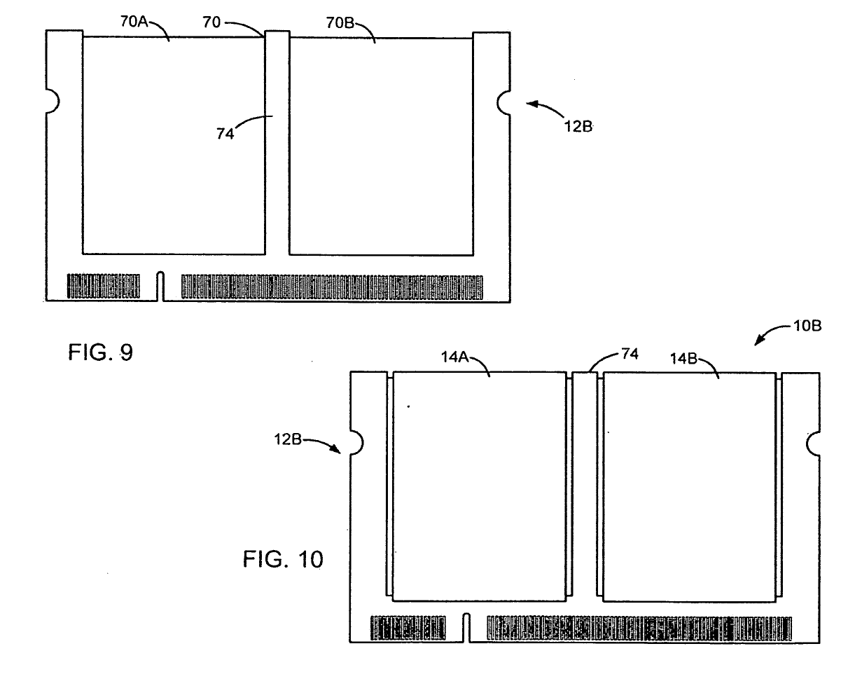

FIGS. 9 and 10 respectively depict another embodiment of a PCB 1 2B and an exemplar module 10B that employs the exemplar PCB 12B of FIG. 9. PCB 12B; of FIG. 9 includes a rib 74 formed across recessed area 70. Rib 74 provides increased rigidity of PCB 12B and strengthens PCB 12B. Rib 74 also divides recessed area 70 into first and second recessed sub-areas 70A, 70B. Although only one side of PCB 12B is depicted, those skilled in the art will appreciate that either a single side or both sides of PCB 12B can include rib 74 and recessed sub-areas 70A, 70B. Contact arrays 30 for connecting the ICs are formed within first and second recessed sub-areas 70A, 70B. Consequently, the ICs attach to the thinnest portions of PCB 12B (i.e., first and second recessed sub-areas 70A, 70B) to reduce the overall thickness of circuit module 10B. As depicted in FIG. 10, circuit module 10B can include first and second heat sinks 14A, 14B. In this embodiment, first heat sink 14A is in heat exchange contact with one or more of the ICs attached in first recessed sub-area 70A, and second heat sink 14B is in heat exchange contact with one or more of the ICs attached in second recessed sub-area 70B. In another embodiment, a single heat sink 14 can be implemented, which is in heat exchange contact with one or more of the ICs attached in first and second recessed sub-areas 70A, 70B. Although not illustrated, it is appreciated that PCB 12B includes contact arrays 30, described in detail above.

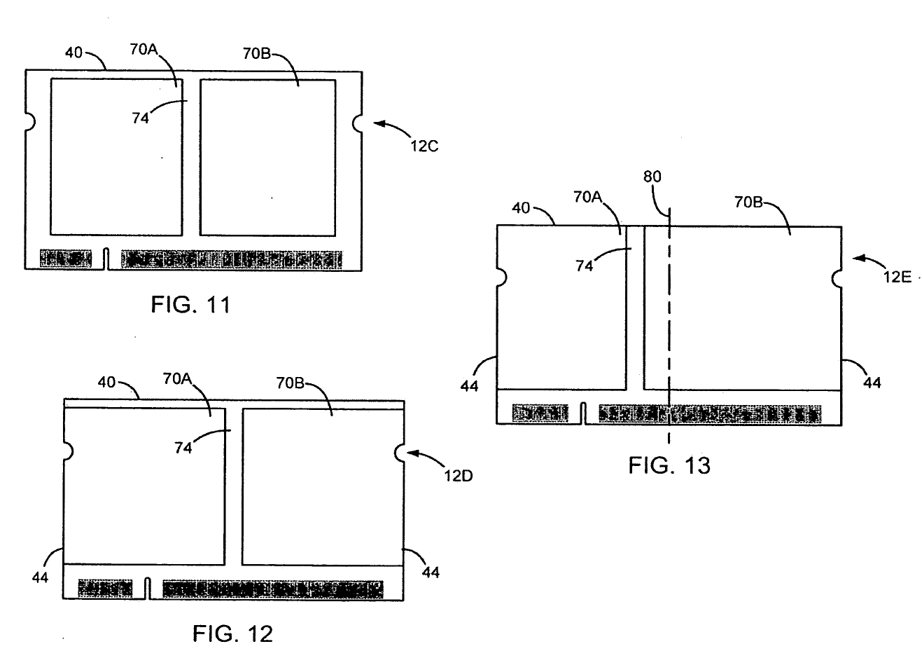

FIGS. 11-13 depict various embodiments of the PCB in accordance with the present disclosure. PCBs 12C, 12D and 12E of FIGS. 11-13, respectively, each include first and second recessed sub-areas 70A, 70B separated by rib 74. Along rib 74, each of the PCBs 12C, 12D and 12E includes a thickness that is greater than second thickness (t₂) of first and second recessed sub-areas 70A, 70B. For example, PCBs 12C, 12D, 12E can each include first thickness (t₁) along rib 74. In PCBs 12C, 12D of FIGS. 11 and 12, respectively, top perimeter edge 40 is not part of either first or second recessed sub-areas 70A, 70B. Along top perimeter edge 40, PCBs 12C, 12D each include a thickness that is greater than second thickness (t₂) of first and second recessed sub-areas 70A, 70B. For example, PCBs 12C, 12D can each include first thickness (t₁) along top perimeter edge 40. In PCBs 12D, 12E of FIGS. 12 and 13, respectively, side perimeter edges 44 form part of the respective first and second recessed sub-areas 70A, 70B. Consequently, along side perimeter edges 44, PCBs 12D, 12E each include the same thickness, for example second thickness (t₂), as it does in first and second recessed sub-areas 70A, 70B. In PCB 12E of FIG. 13, rib 74 is offset from a center line 80 of PCB 12E. As a result, first recessed sub-area 70A is smaller than second recessed sub-area 70B. Although not illustrated, it is appreciated that PCBs 12C-E include contact arrays 30, described in detail above.

Although the present disclosure has been described in detail, it will be apparent to those skilled in the art that many embodiments taking a variety of specific forms and reflecting changes, substitutions and alterations can be made without departing from the spirit and scope of the disclosure. Therefore, the described embodiments illustrate but do not restrict the scope of the claims.

1. A circuit module comprising:
a printed circuit board (PCB) comprising:
a first side, a second side, and a bottom perimeter edge, the PCB exhibiting a first thickness along the bottom perimeter edge, the first side including a first recessed area, the PCB having a second thickness in the first recessed area that is less than the first thickness;
a first plurality of integrated circuits (ICs) fixed to the PCB in the first recessed area; and
a plurality of module contacts connected to the first plurality of ICs, the plurality of module contacts being disposed along at least one of the first and second sides and configured to provide electrical connection between the circuit module and an edge connector.

2. The circuit module of claim 1 in which the PCB also exhibits the first thickness along at least one of a top perimeter edge and side perimeter edges.

3. The circuit module of claim 1 further comprising a second plurality of ICs fixed to the second side of the PCB, at least some of the plurality of module contacts being connected by the plurality of conductive traces to at least one of the second plurality of ICs.

4. The circuit module of claim 3 in which the second side of the PCB includes a second recessed area, the second plurality of ICs being fixed to the PCB in the second recessed area.

5. The circuit module of claim 1 further comprising a heat sink that is located on at least one of the first and second sides of the PCB and that is in heat exchange contact with at least one of the ICs of the first plurality of ICs.

6. The circuit module of claim 5 in which the heat sink wraps around a top perimeter edge of the PCB.

7. The circuit module of claim 1 in which the PCB further comprises at least one rib that divides the first recessed area into a first recessed sub-area and a second recessed sub-area, and in which the PCB exhibits the first thickness along the rib, at least one of the first plurality of ICs being fixed to the PCB in each of the first and second recessed sub-areas.

8. The circuit module of claim 7 further comprising first and second heat sinks that are located on at least one of the first and second sides of the PCB, each of the first and second heat sinks being in heat exchange contact with at least respective ones of the first plurality of ICs fixed in each of the first and second recessed sub-areas.

9. A dual inline memory module (DIMM) comprising:
a printed circuit board (PCB) comprising:
a first side, a second side, and a bottom perimeter edge, the PCB exhibiting a first thickness along the bottom perimeter edge the first side including a first recessed area, the PCB exhibiting a second thickness in the first recessed area that is less than the first thickness;
a first plurality of integrated circuits (ICs) fixed to the PCB in the first recessed area;
a second plurality of ICs fixed to the second side of the PCB;
a plurality of module contacts connected to the first and second pluralities of ICs, the plurality of module contacts being disposed along at least one of the first and second sides; and
a heat sink that is in heat exchange contact with at least one IC of each of the first and second pluralities of ICs.

10. The DIMM of claim 9 in which the PCB also exhibits the first thickness along at least one of a top perimeter edge and side perimeter edges.

11. The DIMM of claim 9 in which the second side of the PCB includes a second recessed area, the second plurality of ICs being fixed to the PCB in the second recessed area.

12. The DIMM of claim 9 in which the heat sink wraps around a top perimeter edge of the PCB.

13. The DIMM of claim 9 in which the PCB further comprises at least one rib that divides the first recessed area into a first recessed sub-area and a second recessed sub-area, the PCB exhibiting the first thickness along the rib, and at least one of the first plurality of ICs being fixed to the PCB in each of the first and second recessed sub-areas.

14. The DIMM of claim 13 further comprising first and second heat sinks that are located on at least one of the first and second sides of the PCB, each of the first and second heat sinks being in heat exchange contact with at least respective ones of the first plurality of ICs fixed in each of the first and second recessed sub-areas.

15. A method of manufacturing a circuit module comprising:
producing a printed circuit board (PCB) having a first side, a second side, and a bottom perimeter edge, the PCB exhibiting a first thickness along the bottom perimeter edge;
forming a first recessed area in the first side of the PCB, the PCB exhibiting a second thickness in the first recessed area that is less than the first thickness;
attaching a first plurality of integrated circuits (ICs) to the PCB in the first recessed area; and
forming a plurality of module contacts along the first and second sides, the plurality of module contacts being connected to the first plurality of ICs and configured to provide electrical connection between the circuit module and an edge connector.

16. The method of claim 15 in which the step of forming includes forming the PCB to also exhibit the first thickness along at least one of a top perimeter edge and side perimeter edges.

17. The method of claim 16 further comprising attaching a second plurality of ICs to a second side of the PCB, the plurality of module contacts being connected to the second plurality of ICs.

18. The method of claim 17 further comprising forming a second recessed area in the second side of the PCB, the second plurality of ICs being attached to the PCB in the second recessed area.

19. The method of claim 15 further comprising attaching a heat sink on at least one of the first and second sides of the PCB, such that the heat sink is in heat exchange contact with at least one of the plurality of ICs.

20. The method of claim 19 in which the heat sink wraps around a top perimeter edge of the PCB.

21. The method of claim 15 further comprising forming at least one rib in the PCB that divides the first recessed area into a first recessed sub-area and a second recessed sub-area, the PCB exhibiting the first thickness along the rib, and at least one of the first plurality of ICs being fixed to the PCB in each of the first and second recessed sub-areas.

22. The method of claim 21 further comprising attaching first and second heat sinks on at least one of the first and second sides of the PCB, each of the first and second heat sinks being in heat exchange contact with at least respective ones of the first plurality of ICs fixed in each of the first and second recessed sub-areas.

23. A dual inline memory module (DIMM) comprising:
a printed circuit board (PCB) comprising:
a first side, a second side, a top perimeter edge, side perimeter edges and a bottom perimeter edge, the PCB exhibiting a first thickness along the bottom perimeter edge and along at least one of the top perimeter edge and the side perimeter edges, the first side including a first recessed area and the second side including a second recessed area, the PCB exhibiting a second thickness between the first and second recessed areas that is less than the first thickness;
a first plurality of integrated circuits (ICs) fixed to the PCB in the first recessed area;
a second plurality of ICs fixed to the PCB in the second recessed area;
a plurality of module contacts connected to the first and second pluralities of ICs, the plurality of module contacts being disposed along at least one of the first and second sides and configured to provide electrical connection between the circuit module and an edge connector; and
a heat sink that is in heat exchange contact with at least one IC of the first and second pluralities of ICs.
